(19) United States
(12) Patent Application Publication
(10) Pub. No.: US 2024/0195197 A1
(43) Pub. Date: Jun. 13, 2024

(54) CONTROLLING BATTERY CHARGING BASED ON STATE OF HEALTH

(71) Applicant: Rivian IP Holdings, LLC, Plymouth, MI (US)

(72) Inventors: Tyler Jennings Bennett, Long Beach, CA (US); Kyle Robert Underhill, Los Angeles, CA (US); Tyler Jay Erikson, Torrance, CA (US); Cuong Cao Nguyen, Aliso Viejo, CA (US); Rutooj Deelip Deshpande, Irvine, CA (US)

(73) Assignee: Rivian IP Holdings, LLC, Plymouth, MI (US)

(21) Appl. No.: 18/062,755

(22) Filed: Dec. 7, 2022

(51) Int. Cl. H02J 7/00; B60L 53/62; B60L 58/16; B60L 58/18; G01R 31/367; G01R 31/392

(52) U.S. Cl. CPC H02J 7/005; B60L 53/62; B60L 58/16; B60L 58/18; G01R 31/367; G01R 31/392; H02J 7/0071; H02J 7/00712; B60L 2250/00

(57) ABSTRACT

Battery charging based on state of health is provided. A state of health if a battery of an electric vehicle is identified. A target state of health is identified based on a life of the battery. An in instruction to charge the battery is conveyed, based on the state of health of the battery and the target state of health for the battery.

### INTRODUCTION

Electric vehicle batteries can be associated with a wear or aging profile. Charging stations can schedule a charging time or rate.

### SUMMARY

Aspects of this technical solution can be directed to charging electric vehicles based on a current battery state of health and a target battery state of health. The state of health can be determined for various electric vehicles, with reference to or based on the target state of health. For example, a target state of health curve can define a target state of health for a battery over time. A battery state of health can deviate from the target state of health (e.g., can age faster or slower than a target rate) according to a use thereof. The systems and methods disclosed herein can charge the battery of an electric vehicle to reduce a number of electric vehicles having a state of health below a target. For example, a charge time or rate for an electric vehicle can be selected to reduce aging, such as delaying a charge completion until a time of use. For a number of electric vehicles exceeding an available number of charging stations or charge capacity, electric vehicles can be ranked (e.g., prioritized) according to a state of health. For example, batteries having a state of health exceeding a target can be charged at individually sub-optimal times to render charging stations available to charge batteries having a state of health less than a target to reduce or eliminate a deviation from the state of health target such that additional vehicles can exceed the target state of health. Thusly, an overall number of vehicles meeting or exceeding a target can be improved, or the battery aging of a fleet can otherwise be managed.

At least one aspect is directed to a system including a one or more processors, coupled with memory. The system can identify a state of health of a battery of an electric vehicle. The system can identify, based on a life of the battery, a target state of health for the battery. The system can provide an instruction to charge the battery of the electric vehicle based on the state of health of the battery and the target state of health for the battery.

At least one aspect is directed to a method. The method includes identifying a state of health of a battery of an electric vehicle. The method can include identifying, based on a life of the battery, a target state of health for the battery. The method can include providing an instruction to charge the battery of the electric vehicle based on the state of health of the battery and the target state of health for the battery. The method can be performed by one or more processors coupled to memory.

At least one aspect is directed to a system. The system includes a data processing system having one or more processors, coupled with memory. The data processing system can be in communication over a network with at least one of a charging station or an electric vehicle connected to the charging station. The data processing system can be configured to identify a state of health of a battery of the electric vehicle. The data processing system can be configured to identify, based on a life of the battery, a target state of health for the battery. The data processing system can be configured to provide an instruction to charge the battery of the electric vehicle. The instruction can be to the charging station or the electric vehicle, based on the state of health of the battery and the target state of health for the battery.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. The foregoing information and the following detailed description and drawings include illustrative examples and should not be considered as limiting.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 depicts a system to monitor and charge an electric vehicle, in accordance with some aspects.

FIG. 2 depicts an electric vehicle, in accordance with some aspects.

FIG. 3 depicts an impact of battery State of Charge on battery Sate of Health, in accordance with some aspects.

FIG. 4 depicts an example display of a facility having various electric vehicles assigned to charging stations, in accordance with some aspects.

FIG. 5 depicts a longitudinal representation of a battery state of an electric vehicle, in accordance with some aspects.

FIG. 6 is a block diagram illustrating a method to charge an electric vehicle, in accordance with some aspects.

FIG. 7 is a block diagram illustrating an architecture for a computer system that can be employed to implement elements of the systems and methods described and illustrated herein.

### DETAILED DESCRIPTION

Following below are more detailed descriptions of various concepts related to, and implementations of, methods, apparatuses, and systems of controlling battery charging based on state of health. The various concepts introduced above and discussed in greater detail below may be implemented in any of numerous ways.

This disclosure is generally directed to adjusting the time at which charging occurs, or adjusting the rate of charge, in accordance with a charging pattern that reduces battery degradation by reducing a window of operation of the battery. To do so, this technology can generate the charging pattern for a battery of an electric vehicle when the vehicle is plugged into a charging station. The technology can generate the charging pattern based on comparing the state of health (“SoH”) of the battery with a target SoH for the battery (e.g., an expected SoH for the battery based on the life of the battery). If, for example, the current SoH of the battery is less than the target SoH, the technology can delay charging of the battery as opposed to charging the battery responsive to being plugged into the charging station, thereby reducing the degradation of the battery. In another example, if the current SoH is greater than the target SoH, then the technology can allow the charging station to charge the battery upon being plugged in. In the event there are multiple vehicles plugged into a charging station, the technology can rank (e.g., prioritize) charging of the multiple vehicles in order to reduce degradation of batteries of electric vehicles having SoH's below the target SoH for the corresponding battery.

The SoH can describe an aging of a battery such as according to a maximum battery capacity. The target SoH can be a battery aging performance target. A battery can receive one or more charges in advance of a scheduled or customary time of use, which can reduce battery aging. For example, a battery having a 1% state of charge can be charged to 50% immediately, and to 100% (or another state of charge) in advance of a use. The charges can be received at a charge rate (e.g., current) to maximize the battery SoH of the electric vehicle or the battery life of further electric vehicles.

The systems and methods herein can be applied to multiple electric vehicles. A household or business can include various electric vehicles or chargers. For example, a number of electric vehicle can exceed an available number of chargers. The electric vehicles can be scheduled for charging according to an expected time of use and an availability of the charging station. The charging station can schedule the vehicles according to an estimated impact to the SoH of the battery with reference to a target SoH. The systems and methods disclosed herein can prioritize the vehicles according to the difference between the target SoH and the SoH. For example, an electric vehicle having a target SoH exceeding an actual SoH can be prioritized relative to an electric vehicle having an actual SoH exceeding a target SoH, such that the SoH of a maximum number of electric vehicles can meet or exceed a target SoH.

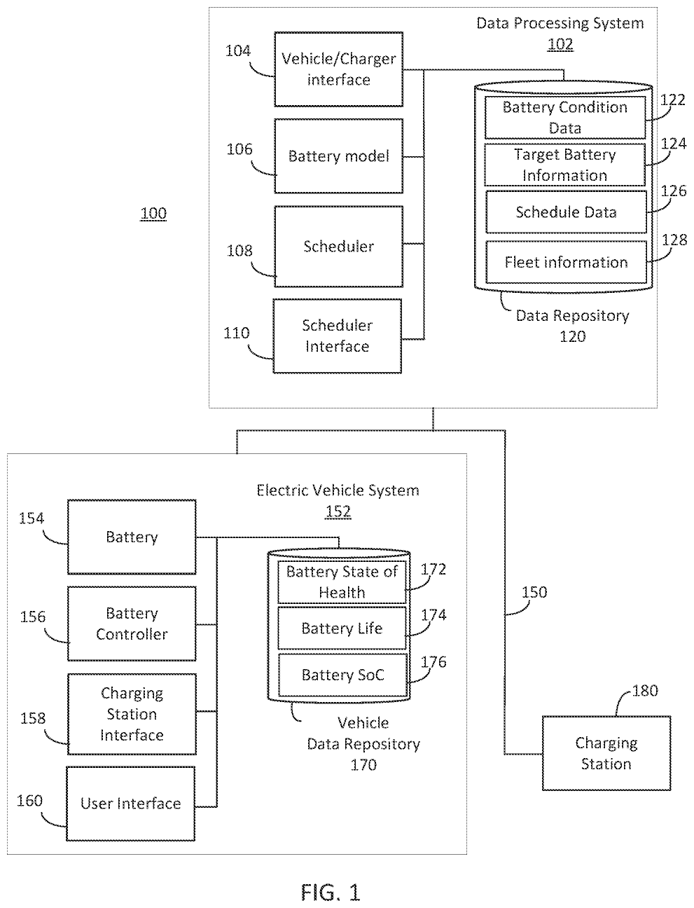

FIG. 1 depicts a system 100 to control battery charging based on state of health, in accordance with some aspects. The system 100 can include, interface with or otherwise communicate with a data processing system 102. The system 100 can include, interface with or otherwise communicate with an electric vehicle system 152. The system 100 can include, interface, or otherwise communicate with a charging station 180. The data processing system 102, the electric vehicle system 152, or the charging station 180 can communicate via a network 150. The network 150 can include computer networks such as the Internet, local, wide, metro, or other area networks, intranets, cellular networks, satellite networks, and other communication networks such as Bluetooth, or data mobile telephone networks. The network 150 can be public or private.

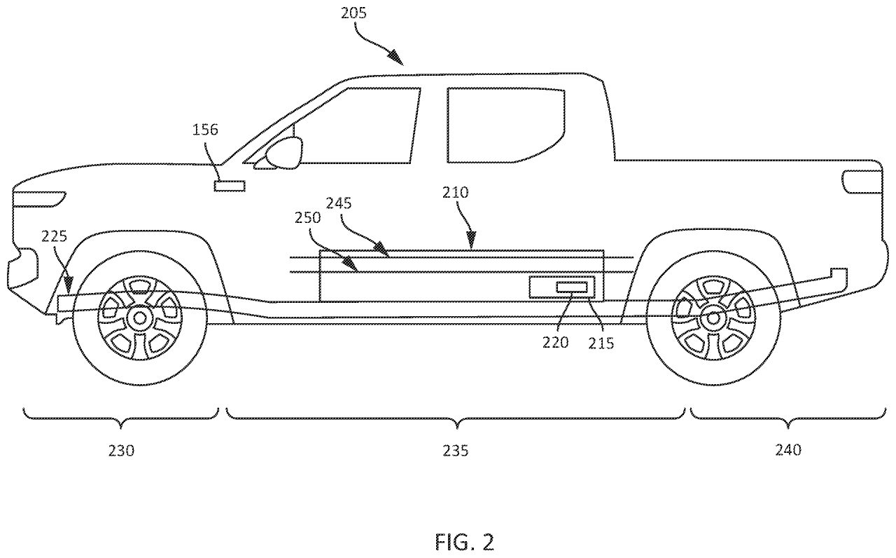

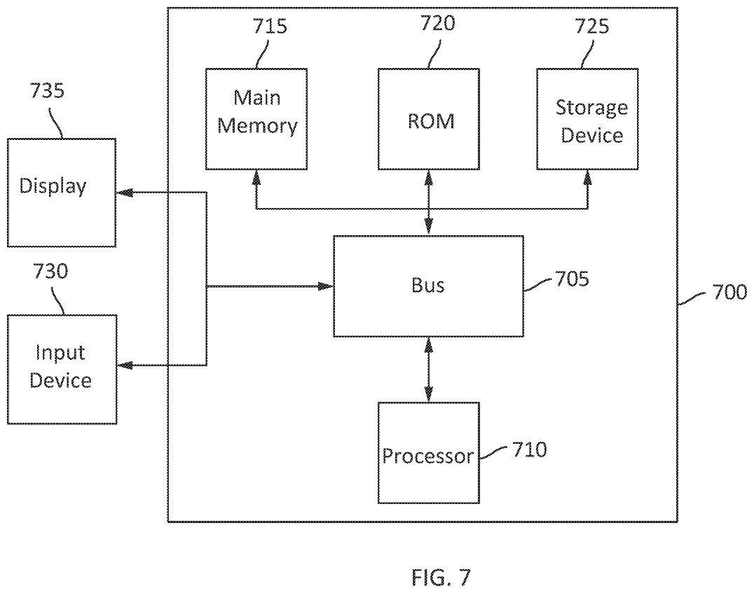

The electric vehicle system 152 can include or be part of an electric vehicle, such as the electric vehicle of FIG. 2. The electric vehicle system 152 can include at least one battery 154. The electric vehicle system 152 can include at least one battery controller 156. The electric vehicle system 152 can include at least one charging station interface 158. The electric vehicle system 152 can include at least one user interface 160. The battery 154, battery controller 156, charging station interface 158, or user interface 160 can each include at least one processing unit or other logic device such as programmable logic array engine, or module configured to communicate with the vehicle data repository 170 or database. The battery 154, battery controller 156, charging station interface 158, or user interface 160 can be separate components, a single component, or part of the electric vehicle system 152. The electric vehicle system 152 can include hardware elements, such as one or more processors, logic devices, or circuits. For example, the electric vehicle system 152 can include one or more components or structures of functionality of computing devices depicted in FIG. 7.

The vehicle data repository 170 can include one or more local or distributed databases, and can include a database management system. The vehicle data repository 170 can include computer data storage or memory and can store one or more of a battery state of health 172 (“SoH”), a battery life 174, or a battery state of charge 176 (“SoC”). The battery SoH can include indications of a health of the battery including a maximum capacity of the battery, a charging efficiency or voltage, or a chemical reaction, such as an oxidation of an anode or a corresponding increase of internal resistance. The battery life 174 can include a number of charge cycles of the battery. The number of charge cycles can be or include an absolute count of charge/discharge cycles, a charge/discharge fractional cycle, a charge/discharge environment, or other quantifiable metrics of the charges or discharges a battery undergone. The battery SoC can include a SoC 176 such as a percent charged (relative to a current or original capacity), a cell voltage, or an amount of energy stored. The SoC 176 can be normalized such as temperature normalized or normalized to the SoH.

The electric vehicle system 152 can include at least one battery 154 designed, constructed, or operational to receive and store a charge for an electric vehicle. For example, the battery 154 can alternatively receive electrical energy for storage as chemical energy by a polymer electrolyte, and thereafter convert at least a portion of the chemical energy to electrical energy, such as to propel an electric vehicle or otherwise cause the operation of other electric vehicle subsystems. The battery 154 can refer to or include a battery cell, battery module, or battery pack. The battery 154 can include a plurality of cells, cell balancing hardware, or a sensor suite reporting in the status of the battery and associated components (e.g., to the battery controller 156). The battery 154 can store energy, and the operations of the battery pack can be configured (e.g., in response to an instruction executed by the battery controller 156). For example, a maximum or minimum battery SoC 176 can be established which can be relevant to the battery SoH 172 of the cells or of other components of the battery 154. The battery 154 can include a thermal management system. The battery 154 can be, include, or be subdivided into modules or submodules which can include or be associated with battery cells and thermal management systems. Each battery 154, battery pack, module, or submodule can include a plurality of cells such as prismatic, cylindrical, rectangular, square, cubic, flat, or pouch form factor cells.

The electric vehicle system 152 can include at least one battery controller 156 designed, constructed, or operational to monitor, charge, discharge, or otherwise interface with the battery 154. For example, the battery controller 156 can provide charging rate or other battery information to a charging station 180 to define or affect a charging rate. The charging rate information can include a temperature, a battery SoC 176, a battery SoH 172, a battery life 174, or a battery identifier. The battery controller 156 can store, retrieve, or convey the battery identifier. For example, the battery identifier can be or include a model number, serial number, date code, vehicle identification number, or batch code. The battery controller 156 can monitor or determine a battery SoC 176, battery SoH 172 or battery life 174. For example, the battery can determine a battery life 174 based on a number, duration, or energy of charge/discharge cycles. The battery controller 156 can detect the number of charge cycles, the amount of energy transferred during a transfer time, or another indication of a battery life 174. The battery controller 156 can determine a SoH 172 or SoC 176 based on a cell, pack, module, or battery 154 voltage, a total energy delivered to the battery, a charging efficiency (e.g., according to a current or thermal measurement). A SoC 176 can be determined based on a SoH, or a SoH can be determined based on a SoC.

The battery controller 156 can be integral to or separate from the battery 154. For example, a battery 154 replacement can include a replacement of the battery controller 156, or the battery controller 156 can determine a battery 154 has been replaced and update various information. For example, the battery controller 156 can be in network communication with the data processing system 102 such that any information determined, measured, or inferred by the battery controller 156 can be presented to the data processing system 102 for processing (such as to determine a battery SoH 172 by a battery model 106). For example, the battery controller 156 can cause a measured current, temperature, or voltage to be conveyed to the data processing system 102.

The electric vehicle system 152 can include at least one charging station interface 158 designed, constructed, or operational to interface to a charging station 180. For example, the charging station interface 158 can include a charging port or receptacle to receive energy from the charger, along with any communicative connections which can be included in the cable (e.g., based on separate or shared conductors), or by various wireless links such as near field communication (NFC), Bluetooth, WiFi, or cellular links. The charging station interface 158 can send or receive commands with the charging station 180. For example, the charging station interface 158 can receive power incident to an instruction from the charging station 180 or an instruction from the electric vehicle system 152. For example, the data processing system 102 can convey a charging instruction to either of the electric vehicle system 152 or the charging station 180. The charging instruction can include a start time (e.g., immediately or delayed), a charge rate (e.g., constant or according to a profile), a sequence to charge electric vehicles, such as an indication to the electric vehicle to receive a reduced power during a time period that another electric vehicle is charging (or an indication to the charging station 180 to supply reduced power).

The electric vehicle system 152 can include at least one user interface 160 designed, constructed, or operational to interface with a user, such as an occupant of an associated electric vehicle. The user interface 160 can provide a prompt to a user, such as to relocate the electric vehicle to one or more charging stations 180, or to connect or disconnect an electric vehicle with a charging station 180. The user interface 160 can receive an entry from a user, such as via a touchscreen, button, or application of a mobile device associated with the electric vehicle. For example, the user can authorize or adjust a proposed charging time, or acknowledge an indication (such as an indication to relocate the electric vehicle). The user interface 160 can display one or more indications of the state of the battery such as a charging rate, battery SoH 172, battery life 174, battery SoC 176, or temperature.

The system 100 can include, interface with, or otherwise utilize one or more charging stations 180 designed, constructed, or operational to provide energy to a battery of one or more electric vehicles. For example, a charging station 180 can include one or more charging points, which can include one or more charging ports or receptacles. For example a charging station (e.g., a 1 MW charging station) can include four charging points (e.g., each being 350 kW maximum such that a maximum of a charging point can depend on a utilization of other charging points). A charging point can include a single port or receptacle or multiple ports or receptacles. The charging station 180 can include parallel connections such that the charging station 180 can simultaneously charge multiple electric vehicles. The charging station 180 or electric vehicles can switch ports or receptacles such as between one or more electric vehicles and the charging station 180. For example, a charging station 180 can include daisy chained charging cables which can be connected to multiple electric vehicles, such that the charging station 180 can charge one or more of the electric vehicles in a sequence (e.g., responsive to an instruction from the data processing system 102). The charging station 180 is sometimes referred to as a charger.

The data processing system 102 can be part of the electric vehicle, charging station 180, or can be or include a remote system, such as a cloud based system. The data processing system 102 can include at least one vehicle or charger interface 104. The data processing system 102 can include at least one battery model 106. The data processing system 102 can include at least one scheduler 108. The data processing system 102 can include at least one scheduler interface 110. The vehicle or charger interface 104, battery model 106, scheduler 108, or scheduler interface 110 can each include at least one processing unit or other logic device such as programmable logic array engine, or module configured to communicate with the data repository 120 or database. The vehicle or charger interface 104, battery model 106, scheduler 108, or scheduler interface 110 can be separate components, a single component, or part of the data processing system 102. The data processing system 102 can include hardware elements, such as one or more processors, logic devices, or circuits. For example, the data processing system 102 can include one or more components or structures of functionality of computing devices depicted in FIG. 7.

The data repository 120 can include one or more local or distributed databases, and can include a database management system. The data repository 120 can include computer data storage or memory and can store one or more of battery condition data 122, target battery information 124, schedule data 126, or fleet information 128. The battery condition data 122 can include the data of various vehicle data repositories associated with various electric vehicles. Target battery information 124 can include a target battery SoH relative to a time in service, battery life, environment, or other information evaluated by the battery model 106. The schedule data 126 can include a known or predicted schedule of one or more electric vehicles, or charging stations 180. Fleet information 128 can include a composition of a fleet such as a health of the fleet, an age of the fleet, a number of expected retirements of the fleet, a battery revision of a fleet vehicle, or prognostic or analytic data for one or more fleet vehicles. The fleet information 128 can include charging station 180 information such as a maximum charging capacity, a plug type, or a maintenance status.

The data processing system 102 can include at least one vehicle or charger interface 104 designed, constructed, or operational to convey information or instructions between the data processing system 102 and the charging station 180 or the electric vehicle system 152. For example, the data processing system 102 can receive status information from one or more charging stations 180, such as a power output available, a connection status relative to one or more electric vehicles (e.g., based on an identifier thereof), or a charging plug or receptacle type or number. The vehicle or charger interface 104 can receive information from the electric vehicle. For example, the vehicle or charger interface 104 can receive any information collected by the battery controller 156 such as information associated with the battery 154 including charging information, thermal or other environmental information, occupancy information, battery SoH 172, life 174, SoC 176, or information relevant thereto. A battery SoH 172 can be determined by the battery model 106, responsive to the information conveyed from the battery controller 156 via the vehicle or charger interface 104.

The vehicle or charger interface 104 can convey instructions to charging stations 180 or electric vehicles, such as to charge the electric vehicles, or perform associated tasks such as relocating a vehicle, or coupling the electric vehicle to the charging station 180. The instructions can cause a notification to be provided to a user, or can initiative an action. The action can be responsive to additional state requirements, such as by a battery controller 156 or charging station 180. For example, an action can be conditional on a temperature, voltage, current, state, or other condition, such as a condition detected by the battery controller 156, charging station interface 158, or charging station 180.

The vehicle or charger interface 104 can determine a communicative connection to a charger or an electric vehicle, and cause a connectivity status to be conveyed to the scheduler 108. The vehicle or charger interface 104 can determine a lack or absence of a communicative connection to a charger or an electric vehicle, and cause the connectivity status to be conveyed to the scheduler 108. The scheduler 108 can schedule cars according to a connectivity status (e.g., electric vehicles lacking connectivity in excess of a threshold can be excluded from a schedule). The scheduler 108 can cause connectivity status to be displayed via the scheduler interface 110 or a user interface 160 of an electric vehicle system 152.

The data processing system 102 can include at least one battery model 106 designed, constructed, or operational to predict, determine, or characterize battery SoH 172 progression. The battery model 106 can include one or more models for each battery 154 or battery type. For example, different vehicles or batteries 154 (e.g., associated information or characteristics such as sizes, layouts, chemistry, date code, or regions) can have different associated battery models 106. The battery model 106 can include machine learning algorithms to predict a functional characteristic of a battery such as voltage, charge or discharge efficiency, or capacity. The battery model 106 can include a physics based model which predicts battery state of health based on chemical reactions within the battery (e.g., between a polymer or other electrolyte and an anode or cathode).

The battery model can be or include an aging curve, depicting a battery SoH 172 relative to battery life 174, battery age, battery or ambient temperature, or other use of the battery 154. The battery model 106 can include a projected impact to battery SoH 172 based on a battery SoC 176. An SoC of 100%, 50% or 0% can result in a different battery SoH. For example, a battery 154 can age (e.g., reduce a battery SoH 172) at a greater rate at an SoC of 0% or 100% than at 50%. The battery model 106 can compare a battery SoH 172 to target battery information 124. The battery model 106 can compare a battery SoH 172 to a modeled battery 154 having a same battery life 174, battery age, or other attribute (such as an installed vehicle, region, customer, service agreement, or use). The battery model 106 can determine a variance between the modeled battery and the battery life 174. For example, a battery SoH 172 can exceed a target or fail to meet a target. The battery model 106 can classify a deviation of a battery SoH 172 from a modeled battery SoH 172. For example, for a battery having a modeled life of 90% of an original capacity, a battery life of 88% can be classified as below target or a battery life of 92% can be classified as above target. The battery model 106 can quantify the variance between a battery SoH 172 and a target SoH.

The data processing system 102 can include at least one scheduler 108 designed, constructed, or operational to schedule a charging of one or more electric vehicles by one or more charging stations 180. The scheduler 108 can receive an aging curve, variance information, or other target battery information 124 from the battery model 106. The scheduler 108 can receive a location, battery SoC 176, battery life 174, other battery condition data 122, schedule data 126, or fleet information 128 for one or more electric vehicles. For example, the scheduler 108 can receive a schedule for one or more vehicles and battery condition data 122 the batteries 154 thereof. The schedule can include a time of anticipated use of the vehicle, a confidence in the time of anticipated use, a route, or an estimated distance traveled for the battery 154. The scheduler 108 can determine a battery 154 use of the electric vehicle such as according to a cargo to be carried, ambient weather conditions, or the battery condition data 122. The scheduler 108 can establish a time or rate (e.g., rate profile) for an electric vehicle to charge. For example, a battery at 65% charge can be charged to 100% for completion immediately before beginning a scheduled route projected to exhaust 95% the battery (e.g., with or without an operating margin).

The scheduler 108 can schedule electric vehicles to charge at a number of charging stations 180. The number of electric vehicles can exceed the number of charging stations 180. For example, the scheduler 108 can schedule twenty electric vehicles to charge from two charging stations 180 or charging points. If a charging time determined for more than one electric vehicle per an available capacity (e.g., of charging stations 180, charging points, or compatible receptacles or plugs) overlaps, an electric vehicle can be prioritized based on the battery SoH 172 of the respective vehicles. For example, a vehicle substantially exceeding (e.g., exceeding by 1%, 5%, or 10%) the target SoH can be deprioritized and the vehicle failing to meet the target SoH can be prioritized, which can converge the battery SoH 172 of various vehicles toward the target SoH.

The scheduler 108 can prioritize or deprioritize based on various factors. For example, an electric vehicle which is not expected to reach a target SoH can be deprioritized (e.g., because of a user intent to decommission the electric vehicle, or relegate the electric vehicle to short trips). The scheduler 108 can receive instructions for a specific electric vehicles or a class of electric vehicles to prioritize or deprioritize. For example, a user can identify one or more vehicles as a long range vehicle, which can be prioritized to maintain a maximum range. The scheduler 108 can prioritize a battery SoH 172 of some vehicles according to a user preference or service contract. For example, the scheduler 108 can maintain a predictable number of vehicles below a threshold (e.g., a retirement threshold), or minimize a number of vehicles for a time period. The scheduler 108 can prioritize or deprioritize an electric vehicle according to a user thereof. For example, if fleet information 128 indicates that 20% of vehicles use about 100 kWh, 30% use 50 kWh, and 50% use about 75 kWh, the scheduler 108 can prioritize or deprioritize a charging to minimize a number of battery replacements over a fixed time period or indefinitely. The scheduler 108 can further schedule charging based on an energy cost, renewable composition, or other energy source parameter.

The data processing system 102 can include at least one scheduler interface 110 designed, constructed, or operational to convey information between the scheduler 108 and one or more users or system components. The scheduler interface 110 can include one or more graphical user interfaces, touchscreens, buttons, network connections, application programming interfaces, or other communicative connections to receive, present, or otherwise convey information related to a schedule for charging an electric vehicle. The scheduler interface 110 can convey any information generated or received from the scheduler 108. For example, the scheduler interface 110 can receive a vehicle prioritization, a schedule (such as a departure time, and a route or a route parameters such as a distance, predicted energy usage, confidence level, or return time). The scheduler interface 110 can present a predicted charge state, an association of one or more vehicles with one or more charging stations 180, groups, or physical locations (e.g., bays, charging stalls, or structures), or information associated with an electric vehicle, such as status of a communicative connection, a battery SoC 176, a battery SoH 172 or target SoH, or a user selectable indication (e.g., “hold for maintenance”).

The scheduler interface 110 can receive an input from a user, such as to adjust a schedule, associate or disassociate a vehicle with a group or physical location, or adjust a status of an electric vehicle or charging station 180 (e.g., available, unavailable, or setting a return or departure time). The scheduler interface 110 can receive an adjustment to a charge location, charge time, charge rate, or other action. The scheduler interface 110 can receive an instruction to relocate an electric vehicle, which can be conveyed to the vehicle or charger interface 104, such as for receipt by an autonomous system or a user interface 160 of an electric vehicle for presentment to a user thereof. The scheduler interface 110 can receive scheduling information relevant to determining or transiting one or more routes. For example, scheduler interface can receive route progress (e.g., positional information), or other information associated with a route for an electric vehicle, such as a cargo weight, a distance, an environmental condition, or a traffic condition.

FIG. 2 depicts an example cross-sectional view of an electric vehicle 205 installed with at least one battery pack 210. Electric vehicles 205 can include electric trucks, electric sport utility vehicles (SUVs), electric delivery vans, electric automobiles, electric cars, electric motorcycles, electric scooters, electric passenger vehicles, electric passenger or commercial trucks, hybrid vehicles, or other vehicles such as sea or air transport vehicles, planes, helicopters, submarines, boats, or drones, among other possibilities. The battery pack 210 can also be used as an energy storage system to power a building, such as a residential home or commercial building. Electric vehicles 205 can be fully electric or partially electric (e.g., plug-in hybrid) and further, electric vehicles 205 can be fully autonomous, partially autonomous, or unmanned. For example, electric vehicles 205 can include autonomous controls to approach, couple, decouple, or vacate a charging station 180. Electric vehicles 205 can also be human operated or non-autonomous. Electric vehicles 205 such as electric trucks or automobiles can include on-board battery packs 210, batteries 154 or battery modules 215, or battery cells 220 to power the electric vehicles. The electric vehicle 205 can include a chassis 225 (e.g., a frame, internal frame, or support structure). The chassis 225 can support various components of the electric vehicle 205. The chassis 225 can span a front portion 230 (e.g., a hood or bonnet portion), a body portion 235, and a rear portion 240 (e.g., a trunk, payload, or boot portion) of the electric vehicle 205. The battery pack 210 can be installed or placed within the electric vehicle 205. For example, the battery pack 210 can be installed on the chassis 225 of the electric vehicle 205 within one or more of the front portion 230, the body portion 235, or the rear portion 240. The battery pack 210 can include or connect with at least one busbar, e.g., a current collector element. For example, the first busbar 245 and the second busbar 250 can include electrically conductive material to connect or otherwise electrically couple the battery 154, the battery modules 215, or the battery cells 220 with other electrical components of the electric vehicle 205 to provide electrical power to various systems or components of the electric vehicle 205.

A battery controller 156 of the electric vehicle 205 can interface with the batteries 154. The batteries 154 can include or be organized into battery packs 210, or battery modules 215. The battery controller 156 can receive instructions to perform the methods disclosed herein. The battery controller 156 can receive instructions from another component of the electric vehicle system 152, the data processing system 102, or the charging station 180. For example, the battery information can include a schedule to charge the electric vehicle 205 based on the battery SoH 172, SoC 176, or battery life 174 information conveyed from the battery controller 156 to the electric vehicle system 152, the data processing system 102, or the charging station 180.

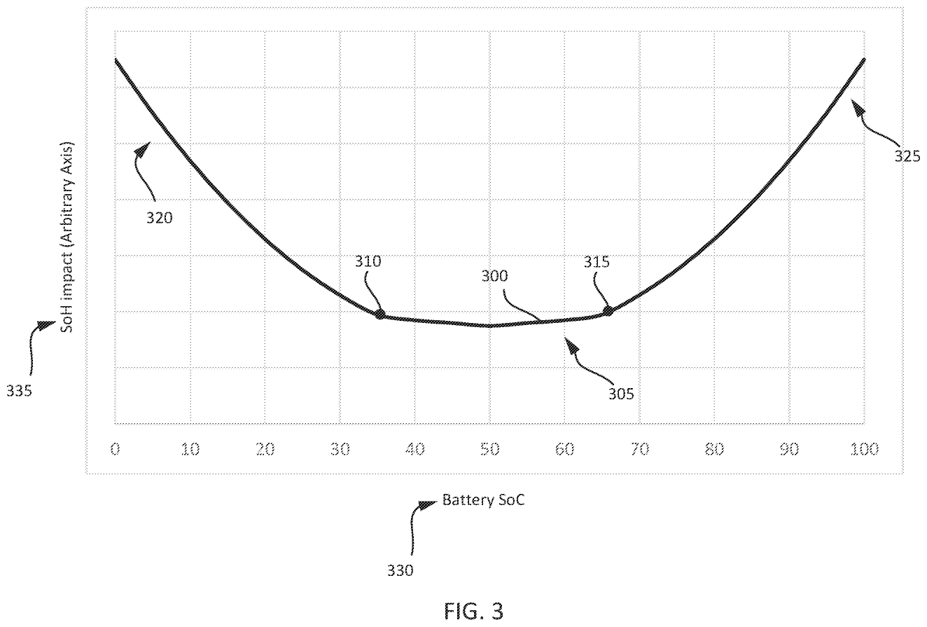

FIG. 3 depicts an impact of battery SoC 176 on battery SoH 172, in accordance with some aspects. An x-axis 330 defines a battery SoC 176 during non-operation. The y-axis 335 defines a SoH impact (e.g., wear or aging) associated with the battery SoC 176. For example, a battery SoH can vary according to a battery SoC 176. Although the depicted scale is arbitrary, one or more unit based scales can be defined. For example, a unit based scale of a change in battery capacity per time unit at a battery SoC 176 can be associated with the y-axis 335. A battery SoH 172 can depend on a battery SoC 176 during an idle state of the electric vehicle 205. For example, the depicted SoC-SoH curve 300 can relate a particular battery chemistry, size, environmental temperature, or initial SoH. The battery model 106 can include various SoC-SoH curves 300 for various parameters. The SoC-SoH curves 300 can be stored as discrete curves SoC-SoH curves 300 or according to one or more functions, models, or other relationships between a use of environment of a battery 154 and an associated battery SoH 172. Further aging curves can be associated with further battery condition data 122. The battery model 106 can aggregate one or more uses, battery types, or environmental conditions, such as to reduce a total number of models. The battery model 106 can refine the predictive quality of the models based on observed battery SoH 172, relative to the model, such as by incorporating changes to a physical model (e.g., adjusting a constant related to temperature or time aging), or by ingesting the information into a predictive or explainable machine learning model. For example, a predictive machine learning model can be trained based on the ingested information, and can thereafter predict an outcome between a battery SoH 172 and the ingested information.

The depicted SoC-SoH curve 300 includes a central portion 305 centered generally about 50% battery SoC 176. A leftmost roll off corner 310 and a rightmost roll off corner 315 bound the central portion 305 from higher wear leftmost 320 and rightmost portions 325. The battery model 106 can associate the SoC-SoH curve 300 (or other aging curves) with one or more battery 154 types, uses, or environments. The depiction is not intended to be limiting. Some battery 154 types, uses, or environmental conditions can be centered around different center points, or include different, additional, or fewer roll off corners. Further aging curves can be included for battery charging, such as according to a charging rate. The scheduler 108 can incorporate aging curves for idle states, charging states, or other non-idle states to determine a cost function to manage a battery SoH 172 for one or more vehicles of the fleet, such as by sequencing a charging schedule based on a vehicle SoH rank (e.g., priority).

The depicted battery SoC axis (from 0 to 100%) can include a total battery capacity or a portion of the battery available during a mode of use. The battery 154 can include reserved, temperature dependent, or other portions such that a battery can exceed 100% charge or discharge below 0%. For example, a battery having 100 kWh of capacity can expose 80 kWh to a user, or utilize 80 kWh during normal operation, or 70 kWh during temperature excursions. The SoC 176 can refer to the 100 kWh, the 80 kWh, or the 70 kWh capacity. The scheduler 108 can include or exclude such regions from consideration. For example, the scheduler 108 can operate within a restricted battery use portion, or can associate a high cost with charging a battery in excess of 100% or discharging a battery below 0%, according to one or more arbitrary scales. For example, the battery model can manage a reserve capacity, or a reserve capacity can be exclusive of management from the scheduler 108.

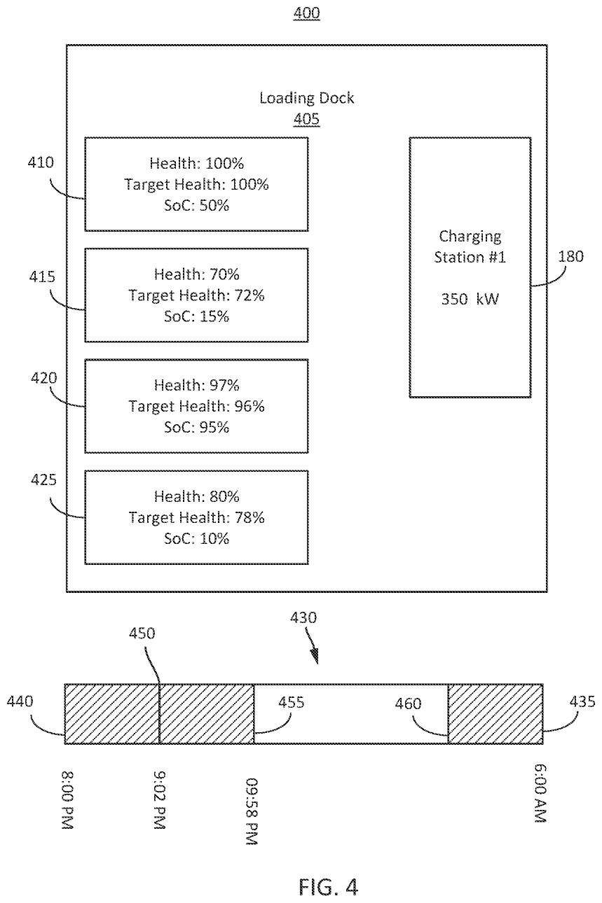

FIG. 4 depicts an example display 400 of a facility having various electric vehicles 205 assigned to charging stations 180, in accordance with some aspects. For example, the scheduler interface 110 can provide a graphical representation of a status of various electric vehicles 205. The electric vehicles 205 can be disposed throughout one or more facilities, which can include physical facilities such as buildings or bays. The scheduler interface 110 can present other subdivisions such as teams or shifts in a similar manner. The display 400 includes a loading dock 405 having four electric vehicles 205 associated therewith. The loading dock 405 can include four electric vehicles 205 along with information thereof. The scheduler interface 110 can present status information such as the battery SoH 172, target SoH, or battery SoC 176 for each electric vehicle 205. The scheduler interface 110 can present one or more charging stations 180 associated with the electric vehicles 205. The scheduler interface 110 can present one or more charging schedules 430 for the electric vehicles 205. For example, the scheduler interface 110 can receive a schedule from the scheduler 108 for presentation.

The scheduler 108 can determine a sequence to charge electric vehicles 205. For example, the scheduler can determine or receive a use time for the vehicle. For example, the use time can be based on a pattern (e.g., a vehicle is started every morning at about eight o'clock) or established schedule, such as a schedule for a delivery service. The scheduler 108 can receive, detect, or infer a pattern for a charge rate of a particular battery or a battery type. For example, a battery charge rate can vary according to an ambient temperature such that a charging rate can be associated with a time of day or forecasted or detected temperature. The scheduler 108 can receive, detect, or infer a pattern for a battery charge rate relative to the battery SoC 176. For example, a battery controller 156 can charge at a first rate at a low battery SoC 176 and a second rate at a higher battery SoC 176. The scheduler 108 can receive, detect, or infer a pattern for a use or condition of a vehicle. For example, a charge rate of a recently used electric vehicle 205 can vary (e.g., according to a temperature or a preconditioning cycle). The scheduler 108 can detect a pattern relating to an availability of energy. For example, a charging station 180 sharing capacity across various charging points can result in a variable energy available at one or more charging points. The scheduler can determine a condition of available energy from a grid (e.g., according to a price, demand reduction request, or quality). The scheduler 108 can schedule an electric vehicle 205 for charging based on the various detected or received patterns.

The scheduler 108 can determine a charge completion time 435 based on the use time of the vehicle. For example, the charge completion time 435 can be the use time or can be offset therefrom (e.g., a charge can be completed 15 minutes prior to the use time). The completion of a charge can be to charge the battery to 100% SoC, or another value, such as 80% SoC, according to a schedule. The scheduler 108 can determine vehicles which are selected for charging charge. For example, the scheduler 108 can determine that the vehicles will use about 60% of their charge the following day, and thus determine that the first associated electric vehicle 410, second associated electric vehicle 415, and fourth associated electric vehicle 425 should be charged, and that the third associated electric vehicle 420 should not be charged. For example, the scheduler 108 can determine that the third associated electric vehicle 420 can complete a route without a charge, and that charging would not positively impact battery SoH 172.

The scheduler 108 can determine that the second associated electric vehicle 415 and the fourth associated electric vehicle 425 should be charged at a first available time 440 to manage battery SoH 172 (e.g., according to a relevant aging curve). The scheduler 108 can determine that the first associated electric vehicle 410 should be charged as late as possible (e.g., according to a relevant aging curve). Thus a latest available time 460 can be assigned to the first associated electric vehicle 410 to charge the first associated electric vehicle 410 to the desired battery SoC 176. The scheduler 108 can detect a contention between the charging times of the second associated electric vehicle 415 and the fourth associated electric vehicle 425. The scheduler 108 can prioritize the fourth associated electric vehicle 425 relative to the second associated electric vehicle 415 to resolve the contention, based on the differences between the target SoH and the battery SoH 172. Thus, the fourth associated electric vehicle 425 can be scheduled to charge at the first available time 440, and the second associated electric vehicle 415 can be charged beginning at a second available time 450 (e.g., immediately following the first available time, offset therefrom to allow a recoupling time, or in a next available time slice such as an hourly or bihourly time slice.) The second associated electric vehicle 415 can complete charging at a completion time 455 according to a desired state of charge (e.g., 50%, 80%, or 90%). The scheduler interface 110 can further provide an indication to connect one or more electric vehicles 205 to a charging station 180, in accordance with the determinations of the scheduler 108. The scheduler 108 can schedule one or more electric vehicles 205 for simultaneous charging for a charging stations 180 having multiple ports or receptacles wherein the charging station 180 power exceeds the maximum power draw of the combined electric vehicle 205 (e.g., according to a charging profile determined, estimated, or received by the scheduler 108).

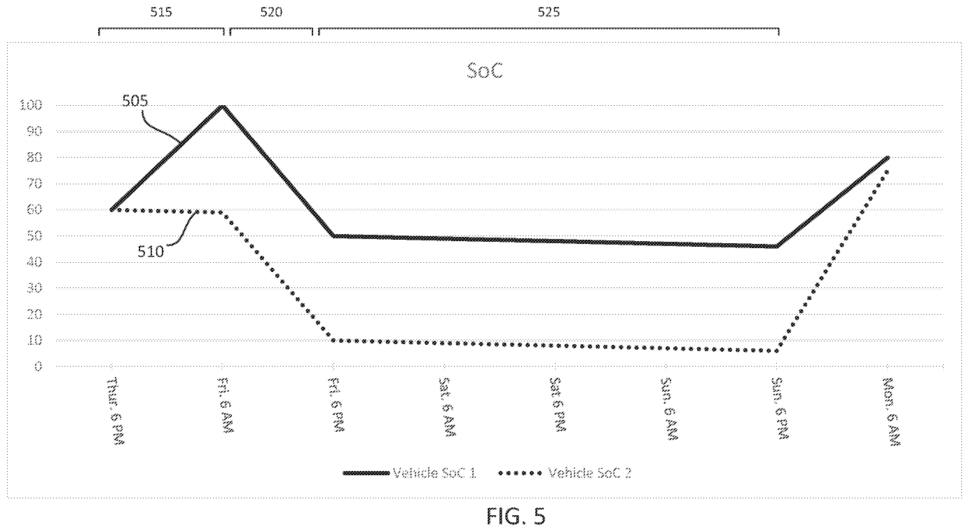

FIG. 5 depicts a longitudinal representation 500 of battery SoC 176 of an electric vehicle 205, in accordance with some aspects. For example, the longitudinal representation 500 can be predicted by the scheduler 108 or can be measured by the battery controller 156. The scheduler 108 can generate the longitudinal representations 500 as two battery SoC 176 projections, such as alternate schedules for one electric vehicle 205. The first use projection 505 and the second use projection 510 both begin with a charge of about 60%. The first use projection 505 is charged to 100 percent in during a first period 515, the first period 515 representing a period of non-use of an associated electric vehicle 205. According to some SoC-SoH curves 300, such as the SoC-SoH curve 300 depicted in FIG. 3, the first use projection 505 can include increased battery SoH degradation during this period, relative to the second use projection 510.

During a second period 520, the battery SoC 176 is discharged about 50 percent of a total capacity. For example, the second period 520 can include a period of use such as navigating a scheduled route. The first use projection 505 completes second period 520 at a battery SoC of about 50 percent. The second use projection 510 completes the second period 520 at a battery SoC 176 of about 10 percent. A third period 525 can include substantial idle time. The battery SoC 176 can remain measurably constant during idle time or can discharge according to a self-discharge of the battery or any active systems of the electric vehicle 205 such as electric vehicle system 152 components. The battery model 106 can determine an impact to the battery SoH 172 of the first use projection 505 relative to the second use projection 510 for this period. The scheduler 108 can select a use projection based on the impact of each of the use projection to an overall impact to battery SoH 176. For example, the scheduler 108 can receive a predicted change to a battery SoH 176 from the battery model 106 and select a use projection resulting a greater battery SoH 172. Particularly, the battery model 106 can determine if the battery life 174 impact (e.g., the additional charge cycle) of the first use projection 505 causes a greater impact to battery SoH 172 than the period of time at low battery SoC 176 of the second use projection 510.

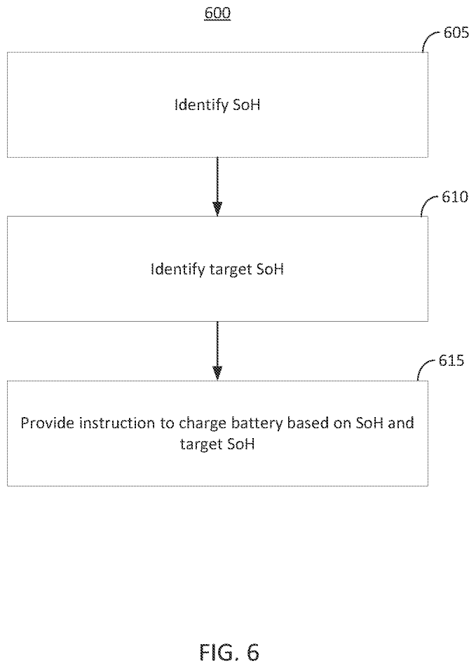

FIG. 6 is a block diagram illustrating a method 600 to charge an electric vehicle 205, in accordance with some aspects. The method 600 can be performed by one or more components or systems depicted in FIG. 1, 2, 4, or 7 including, for example, the system 100. At ACT 605, a data processing system 102 can identify a battery SoH 172 of an electric vehicle 205. At ACT 610, a data processing system 102 can determine a target SoH for the battery 154 of the electric vehicle 205. At ACT 615, a data processing system 102 can provide an instruction to charge the battery 154 of the electric vehicle 205 based on the identified battery SoH 172 and the target SoH.

At ACT 605, the data processing system 102 can identify a battery SoH 172. For example, the data processing system 102 can identify the battery SoH 172 based on information received from the battery controller 156. The information received from the battery controller 156 can include the battery SoH 172, a preliminary battery SoH 172, or information relevant to determining the battery SoH. For example, the vehicle or charger interface 104 can receive information related to a charge provided to the battery 154, an environment of the battery 154 or a voltage of one or more cells of the battery 154 (e.g., of a battery module 215, submodule, or pack 210). The data processing system 102 can identify the battery SoH 172 based on various measurements taken over time, such as a 30 day rolling period.

At ACT 610, the data processing system 102 can identify a target SoH of the battery. The data processing system 102 can identify the target SoH according to an typical SoH. For example, a median SoH of a population such as a customer population, a regional population, or a use population of electric vehicles. The data processing system 102 (e.g., the battery model 106) can identify a momentary target SoH (e.g., at a single point in time), or can identify an aging curve defining a target SoH such as a monthly, annual, or daily target SoH, or a continuous function. The data processing system 102 can identify the target SoH based on an age of the battery or a battery life 174 (e.g., number of charge cycles). The data processing system 102 can identify the target SoH based on a batch number, revision, or other battery 154 identifier. The data processing system 102 can determine the target SoH based on information received from the battery controller 156, such as an operational environment or use (e.g., some uses use can be associated with a higher or lower target SoH). The data processing system 102 can determine the target SoH based on an input received from the scheduler interface 110, such as a request to extend the use of a vehicle, or an intention to decommission a vehicle.

AT ACT 615, the data processing system 102 can provide an instruction to charge the battery 154 of the electric vehicle 205 based on the battery SoH 172 and the target SoH of the battery. The data processing system 102 can convey the instruction over a network 150 including the battery controller 156 or the charging station 180. For example, the instruction can be addressed to the battery controller 156 or the charging station 180 to execute the instruction to charge the electric vehicle 205.

FIG. 7 is a block diagram illustrating an architecture for a computer system that can be employed to implement elements of the systems and methods described and illustrated herein. The computer system or computing device 700 can include or be used to implement a data processing system or its components. The computing system 700 includes at least one bus 705 or other communication component for communicating information and at least one processor 710 or processing circuit coupled to the bus 705 for processing information. The computing system 700 can also include one or more processors 710 or processing circuits coupled to the bus for processing information. The computing system 700 also includes at least one main memory 715, such as a random access memory (RAM) or other dynamic storage device, coupled to the bus 705 for storing information, and instructions to be executed by the processor 710. The main memory 715 can be used for storing information during execution of instructions by the processor 710. The computing system 700 may further include at least one read only memory (ROM) 720 or other static storage device coupled to the bus 705 for storing static information and instructions for the processor 710. A storage device 725, such as a solid state device, magnetic disk or optical disk, can be coupled to the bus 705 to persistently store information and instructions.

The computing system 700 may be coupled via the bus 705 to a display 735, such as a liquid crystal display, or active matrix display, for displaying information to a user such as a driver of the electric vehicle 205 or other end user. An input device 730, such as a keyboard or voice interface may be coupled to the bus 705 for communicating information and commands to the processor 710. The input device 730 can include a touch screen display 735. The input device 730 can also include a button, network connection, application programming interface, or other communicative connection for communicating information, acknowledgements, or selections to the processor 710.

The processes, systems and methods described herein can be implemented by the computing system 700 in response to the processor 710 executing an arrangement of instructions contained in main memory 715. Such instructions can be read into main memory 715 from another computer-readable medium, such as the storage device 725. Execution of the arrangement of instructions contained in main memory 715 causes the computing system 700 to perform the illustrative processes described herein. One or more processors in a multi-processing arrangement may also be employed to execute the instructions contained in main memory 715. Hard-wired circuitry can be used in place of or in combination with software instructions together with the systems and methods described herein. Systems and methods described herein are not limited to any specific combination of hardware circuitry and software.

Although an example computing system has been described in FIG. 7, the subject matter including the operations described in this specification can be implemented in other types of digital electronic circuitry, or in computer software, firmware, or hardware, including the structures disclosed in this specification and their structural equivalents, or in combinations of one or more of them.

Some of the description herein emphasizes the structural independence of the aspects of the system components or groupings of operations and responsibilities of these system components. Other groupings that execute similar overall operations are within the scope of the present application. Modules can be implemented in hardware or as computer instructions on a non-transient computer readable storage medium, and modules can be distributed across various hardware or computer based components.

The systems described above can provide multiple ones of any or each of those components and these components can be provided on either a standalone system or on multiple instantiation in a distributed system. In addition, the systems and methods described above can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. In general, the computer-readable programs can be implemented in any programming language, such as LISP, PERL, C, C++, C#, PROLOG, or in any byte code language such as JAVA. The software programs or executable instructions can be stored on or in one or more articles of manufacture as object code.

Example and non-limiting module implementation elements include sensors providing any value determined herein, sensors providing any value that is a precursor to a value determined herein, datalink or network hardware including communication chips, oscillating crystals, communication links, cables, twisted pair wiring, coaxial wiring, shielded wiring, transmitters, receivers, or transceivers, logic circuits, hard-wired logic circuits, reconfigurable logic circuits in a particular non-transient state configured according to the module specification, any actuator including at least an electrical, hydraulic, or pneumatic actuator, a solenoid, an op-amp, analog control elements (springs, filters, integrators, adders, dividers, gain elements), or digital control elements.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices include cloud storage). The operations described in this specification can be implemented as operations performed by a data processing apparatus on data stored on one or more computer-readable storage devices or received from other sources.

The terms “computing device”, “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. References to at least one of a conjunctive list of terms may be construed as an inclusive OR to indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

For example, descriptions of positive and negative electrical characteristics may be reversed. For example, an electric vehicle 205 can supply voltage to a charging station 180 such as to cross level power or reduce a power level for storage. Elements described as negative elements can instead be configured as positive elements and elements described as positive elements can instead by configured as negative elements. For example, elements described as having first polarity can instead have a second polarity, and elements described as having a second polarity can instead have a first polarity. Further relative parallel, perpendicular, vertical or other positioning or orientation descriptions include variations within +/−10% or +/−10 degrees of pure vertical, parallel or perpendicular positioning. References to “approximately,” “substantially” or other terms of degree include variations of +/−10% from the given measurement, unit, or range unless explicitly indicated otherwise. Coupled elements can be electrically, mechanically, or physically coupled with one another directly or with intervening elements. Scope of the systems and methods described herein is thus indicated by the appended claims, rather than the foregoing description, and changes that come within the meaning and range of equivalency of the claims are embraced therein.

What is claimed is:

1. A system, comprising:
one or more processors, coupled with memory, to:
identify a state of health of a battery of an electric vehicle;
identify, based on a life of the battery, a target state of health for the battery; and
provide an instruction to charge the battery of the electric vehicle based on the state of health of the battery and the target state of health for the battery.

2. The system of claim 1, comprising the one or more processors to:
identify the state of health of the battery responsive to a connection between the electric vehicle and a charging station configured to charge the battery;
generate, based on a comparison of the state of health of the battery with the target state of health for the battery, a charge pattern for the battery, the charge pattern indicating one or more time intervals to charge the battery and one or more rates at which to charge the battery in the one or more time intervals; and
generate the instruction to charge the battery based on the charge pattern.

3. The system of claim 1, comprising the one or more processors to:
detect a connection between the electric vehicle and a charging station configured to charge the battery of the electric vehicle; and
determine, based on a comparison of the state of health of the battery with the target state of health for the battery, to delay a charging session to charge the battery.

4. The system of claim 1, comprising the one or more processors to:
determine, based on a comparison of the state of health of the battery with the target state of health for the battery, to delay a charging session to charge the battery; and
provide, via a user interface of the electric vehicle, an indication of the delay.

5. The system of claim 1, comprising the one or more processors to:
determine, based on a comparison of the state of health of the battery with the target state of health for the battery, to delay a charging session to charge the battery;
provide, via a user interface of the electric vehicle, a prompt for authorization to delay the charging session to charge the battery; and
generate, based on input received via the user interface responsive to the prompt, the instruction to charge the battery.

6. The system of claim 1, comprising the one or more processors to:
determine the life of the battery based on a number of charge or discharge cycles performed by the battery.

7. The system of claim 1, comprising the one or more processors to:
determine, based on a comparison of the state of health of the battery with the target state of health for the battery, that the state of health of the battery is less than the target state of health for the battery; and
generate the instruction to delay a charging session for the battery responsive to the state of health of the battery being less than the target state of health for the battery.

8. The system of claim 1, comprising the one or more processors to:
determine, based on a comparison of the state of health of the battery with the target state of health for the battery, that the state of health of the battery is greater than the target state of health for the battery; and
generate, based on the state of health of the battery being greater than the target state of health, the instruction to begin a charging session for the battery responsive to a connection between the electric vehicle and a charging station.

9. The system of claim 1, comprising the one or more processors to:
identify a plurality of states of health and a plurality of lives corresponding to a plurality of batteries corresponding to a plurality of electric vehicles connected to one or more charging stations;
identify a plurality of target states of health for the plurality of batteries based on the plurality of lives;
rank, based on a comparison of the plurality of states of health and the plurality of target states of health, the plurality of electric vehicles for charging by the one or more charging stations; and
generate a schedule to charge the plurality of electric vehicles based on the rank.

10. The system of claim 1, comprising the one or more processors to:
identify a plurality of states of health and a plurality of lives corresponding to a plurality of batteries corresponding to a plurality of electric vehicles connected to one or more charging stations;
identify a plurality of target states of health for the plurality of batteries based on the plurality of lives;
rank, based on a comparison of the plurality of states of health and the plurality of target states of health, the plurality of electric vehicles for charging by the one or more charging stations;
identify an operation schedule for the plurality of electric vehicles; and
generate a schedule to charge the plurality of electric vehicles based on the rank and the operation schedule.

11. The system of claim 1, comprising the one or more processors to:
identify a second state of health of a second battery of a second electric vehicle, wherein the second electric vehicle connects to a charging station prior to the electric vehicle;
identify, based on a second life of the second battery, a second target state of health for the second battery;
determine that i) the second target state of health is greater than the second life of the second battery, and ii) that the target state of health of the battery is less than or equal to the state of health of the battery; and
instruct, based on the determination, the charging station to charge the battery prior to the second battery.

12. The system of claim 1, comprising the one or more processors to:
access a model configured based on a chemistry of the battery and trained via machine learning; and
determine, via the life of the battery input into the model, the target state of health of the battery.

13. A method, comprising:
identifying, by one or more processors coupled with memory, a state of health of a battery of an electric vehicle;
identifying, by the one or more processors based on a life of the battery, a target state of health for the battery; and
providing, by the one or more processors, an instruction to charge the battery of the electric vehicle based on the state of health of the battery and the target state of health for the battery.

14. The method of claim 13, comprising:
identifying, by the one or more processors, the state of health of the battery responsive to a connection between the electric vehicle and a charging station configured to charge the battery;
generating, by the one or more processors, based on a comparison of the state of health of the battery with the target state of health for the battery, a charge pattern for the battery, the charge pattern indicating one or more time intervals to charge the battery and one or more rates at which to charge the battery in the one or more time intervals; and
generating, by the one or more processors, the instruction to charge the battery based on the charge pattern.

15. The method of claim 13, comprising:
detecting, by the one or more processors, a connection between the electric vehicle and a charging station configured to charge the battery of the electric vehicle; and
determining, by the one or more processors based on a comparison of the state of health of the battery with the target state of health for the battery, to delay a charging session to charge the battery.

16. The method of claim 13, comprising:
determining, by the one or more processors, based on a comparison of the state of health of the battery with the target state of health for the battery, to delay a charging session to charge the battery; and
providing, by the one or more processors via a user interface of the electric vehicle, an indication of the delay.

17. The method of claim 13, comprising:
determining, by the one or more processors, based on a comparison of the state of health of the battery with the target state of health for the battery, to delay a charging session to charge the battery;
providing, by the one or more processors via a user interface of the electric vehicle, a prompt for authorization to delay the charging session to charge the battery; and
generating, by the one or more processors, based on input received via the user interface responsive to the prompt, the instruction to charge the battery.

18. The method of claim 13, comprising:
determining, by the one or more processors, the life of the battery based on a number of charge or discharge cycles performed by the battery.

19. A system, comprising:
a data processing system comprising one or more processors, coupled with memory, in communication over a network with at least one of a charging station or an electric vehicle connected to the charging station, the data processing system configured to:
identify a state of health of a battery of the electric vehicle;
identify, based on a life of the battery, a target state of health for the battery; and
provide, to the charging station or the electric vehicle, based on the state of health of the battery and the target state of health for the battery, an instruction to charge the battery of the electric vehicle.

20. The system of claim 19, comprising the data processing system to:
identify the state of health of the battery responsive to establishment of a connection between the electric vehicle and the charging station;
generate, based on a comparison of the state of health of the battery with the target state of health for the battery, a charge pattern for the battery, the charge pattern indicating one or more time intervals to charge the battery and one or more rates at which to charge the battery in the one or more time intervals; and
generate the instruction to charge the battery based on the charge pattern.
